(19) United States
(12) Patent Application Publication
(10) Pub. No.: US 2015/0055309 A1
(43) Pub. Date: Feb. 26, 2015

(54) ELECTRONIC COMPONENT EMBEDDED SUBSTRATE AND METHOD OF MANUFACTURING ELECTRONIC COMPONENT EMBEDDED SUBSTRATE

(71) Applicant: SAMSUNG ELECTRO-MECHANICS CO., LTD., Suwon (KR)

(72) Inventors: Tae Kyun BAE, Yeongi-gun (KR); Doo Hwan Lee, Daejeon (KR)

(73) Assignee: SAMSUNG ELECTRO-MECHANICS CO., LTD., Suwon (KR)

(21) Appl. No.: 14/132,583

(22) Filed: Dec. 18, 2013

(30) Foreign Application Priority Data
Aug. 20, 2013 (KR) 10-2013-0098594

(51) Int. Cl. H01L 23/31; H01L 23/48; H01L 21/56

(52) U.S. Cl. CPC H01L 23/3114; H01L 21/561; H01L 23/481
USPC 361/761; 438/126

(57) ABSTRACT

The present invention can improve efficiency of a process of forming a via for connecting an electronic component embedded in a substrate to external wiring by including an electronic component having at least one external terminal on at least one surface thereof; a third insulating layer having a second circuit pattern on one surface thereof and a cavity to insert the electronic component therein; a fourth insulating layer provided on the third insulating layer and the electronic component; a first via having one surface in contact with the second circuit pattern through the fourth insulating layer; a second via having one surface in contact with the external terminal through the fourth insulating layer; and a fourth circuit pattern provided on an outer surface of the fourth insulating layer to be in contact with the other surface of the first via and the other surface of the second via.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2013-0098594, entitled filed Aug. 20, 2013, which is hereby incorporated by reference in its entirety into this application.

### BACKGROUND OF THE INVENTION

1. Field of the Invention

The present invention relates to an electronic component embedded substrate and a method of manufacturing an electronic component embedded substrate.

2. Description of the Related Art

In order to respond to the trend of light, small, high-speed, multifunctional, and high-performance electronic devices, multilayer substrate technologies to form a plurality of wiring layers on a printed circuit board (PCB) have been developed, and furthermore, technologies to embed an electronic component such as an active device or a passive device in a multilayer substrate also have been developed.

For example, in Patent Document 1, a PCB, which inserts an electronic component in a cavity and consists of a plurality of layers, and a method of manufacturing the same are disclosed.

Meanwhile, one of the important tasks in the field of the multilayer substrate is to allow an embedded electronic component to efficiently transceive signals including a voltage or a current with external circuits or other devices.

Further, recently, as the trend of high-performance electronic components and the trend of small and thin electronic components and electronic component embedded substrates are intensified, improvement of integration of circuit patterns should be essentially accompanied to connect an external terminal of the electronic component to external wiring while embedding the small electronic component in the thinner and narrower substrate.

Meanwhile, when an electronic component is mounted inside a cavity of a core substrate, it is not possible to efficiently perform a via hole forming process, a conductive material plating process, etc, due to the difference in the height between a via in contact with an upper surface of a circuit pattern provided on the surface of the core substrate and a via in contact with an upper surface of an external terminal of the electronic component.

### RELATED ART DOCUMENT

### Patent Document

Patent Document 1: U.S. Patent Laid-open Publication No. 2012-0006469
Patent Document 2: Japanese Patent Laid-open Publication No. 2000-261124

### SUMMARY OF THE INVENTION

The present invention has been invented in order to overcome the above-described problems and it is, therefore, an object of the present invention to provide an electronic component embedded substrate and a method of manufacturing an electronic component embedded substrate that can improve efficiency of a process of forming a via for connecting an electronic component embedded in a substrate to external wiring. Furthermore, it is an object of the present invention to provide an electronic component embedded substrate and a method of manufacturing an electronic component embedded substrate that can minimize unnecessary wiring while reducing warpage.

In accordance with one aspect of the present invention to achieve the object, there is provided an electronic component embedded substrate including: an electronic component having at least one external terminal on at least one surface thereof; a third insulating layer having a second circuit pattern on one surface thereof and a cavity to insert the electronic component therein; a fourth insulating layer provided on the third insulating layer and the electronic component; a first via having one surface in contact with the second circuit pattern through the fourth insulating layer; a second via having one surface in contact with the external terminal through the fourth insulating layer; and a fourth circuit pattern provided on an outer surface of the fourth insulating layer to be in contact with the other surface of the first via and the other surface of the second via.

At this time, the first via and the second via may have the same distance from one surface to the other surface.

Further, the electronic component embedded substrate may further include a first insulating layer provided on the other surface of the electronic component and the other surface of the third insulating layer; and a second insulating layer provided between the other surface of the third insulating layer and the first insulating layer.

Further, the third insulating layer may further include a through via passing through the third insulating layer; and a first circuit pattern electrically connected to the second circuit pattern by the through via.

Further, the second insulating layer may be formed to cover the second circuit pattern and a third via hole which exposes the second circuit pattern through the first insulating layer and the second insulating layer may be further included.

Further, it is preferred that an insulating material forming the fourth insulating layer has a lower coefficient of thermal expansion than an insulating material forming the first insulating layer.

Further, the electronic component embedded substrate may further include at least one build-up layer provided on the fourth insulating layer, and it is preferred that an insulating material forming the build-up layer has a lower coefficient of thermal expansion than the insulating material forming the first insulating layer.

Further, it is preferred that the first circuit pattern is in contact with the first insulating layer and a third via hole which exposes the first circuit pattern through the first insulating layer is further included.

Further, the electronic component embedded substrate may further include an adhesive member having one surface in contact with the other surface of the electronic component.

Further, the electronic component embedded substrate may further include a metal pattern having one surface in contact with the other surface of the adhesive member.

Further, the electronic component embedded substrate may further include a fourth via hole which exposes the metal pattern to the outside through the first insulating layer.

Further, the first via may have a larger volume than the second via.

In accordance with another aspect of the present invention to achieve the object, there is provided a method of manufacturing an electronic component embedded substrate, including the steps of: providing a third insulating layer which is penetrated by a cavity, has a second circuit pattern on one surface thereof, has a first circuit pattern on the other surface thereof, and electrically connects the second circuit pattern and the first circuit pattern by a through via; disposing an electronic component, which has at least one external terminal on at least one surface thereof, and the third insulating layer on a first insulating layer; forming a fourth insulating layer on the third insulating layer and the electronic component; forming a first via hole, which exposes the second circuit pattern through the fourth insulating layer, and a second via hole, which exposes the external terminal through the fourth insulating layer; and forming a first via by filling a conductive material in the first via hole, forming a second via by filling a conductive material in the second via hole, and forming a fourth circuit pattern on the fourth insulating layer.

At this time, the first via and the second via may have the same distance from one surface to the other surface.

Further, in the step of providing the third insulating layer, a second insulating layer may be further formed to cover the other surface of the third insulating layer.

Further, an insulating material forming the fourth insulating layer may have a lower coefficient of thermal expansion than an insulating material forming the first insulating layer.

Further, the method of manufacturing an electronic component embedded substrate may further include the step of forming at least one build-up layer on the fourth insulating layer, and an insulating material forming the build-up layer may have a lower coefficient of thermal expansion than the insulating material forming the first insulating layer.

Further, the method of manufacturing an electronic component embedded substrate may further include the step of forming a via hole passing through the first insulating layer.

Further, the first via may have a larger volume than the second via.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view schematically showing an electronic component embedded substrate in accordance with an embodiment of the present invention;

FIG. 2 is a cross-sectional view schematically showing an electronic component embedded substrate in accordance with another embodiment of the present invention; and

FIGS. 3A to 3i are process cross-sectional views for explaining a method of manufacturing an electronic component embedded substrate in accordance with an embodiment of the present invention, wherein FIG. 3A is a process cross-sectional view showing the state in which a through via hole is formed in a third insulating layer in accordance with an embodiment of the present invention, FIG. 3B is a process cross-sectional view showing the state in which a first circuit pattern, a second circuit pattern, and a through via are formed in accordance with an embodiment of the present invention, FIG. 3C is a process cross-sectional view showing the state in which a cavity and a second insulating layer are formed in accordance with an embodiment of the present invention, FIG. 3D is a process cross-sectional view showing the state in which the third insulating layer and an electronic component are coupled on a first insulating layer in accordance with an embodiment of the present invention, FIG. 3E is a process cross-sectional view showing the state in which a fourth insulating layer is formed in accordance with an embodiment of the present invention, FIG. 3F is a process cross-sectional view showing the state in which a first via hole and a second via hole are formed in accordance with an embodiment of the present invention, FIG. 3G is a process cross-sectional view showing the state in which a first via, a second via, and a fourth circuit pattern are formed in accordance with an embodiment of the present invention, FIG. 3H is a process cross-sectional view showing the state in which a build-up layer is further formed in accordance with an embodiment of the present invention, and FIG. 3I is a process cross-sectional view showing the state in which a third via hole, a fourth via hole, and a seventh insulating layer are formed in accordance with an embodiment of the present invention.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and operational effects of the present invention will be described in detail with reference to the accompanying drawings.

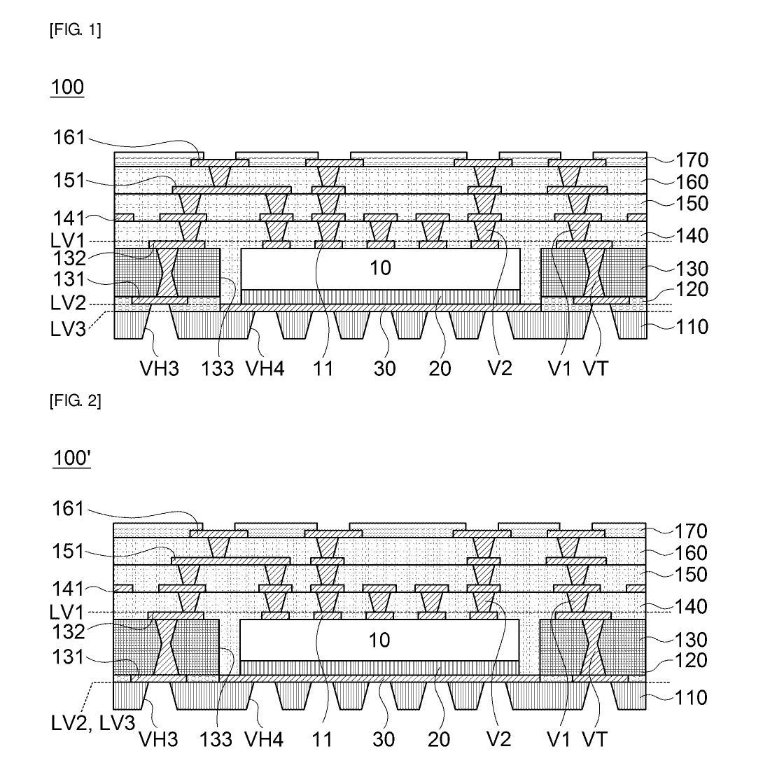

FIG. 1 is a cross-sectional view schematically showing an electronic component embedded substrate 100 in accordance with an embodiment of the present invention.

Referring to FIG. 1, the electronic component embedded substrate 100 in accordance with an embodiment of the present invention may include an electronic component 10, a third insulating layer 130, a fourth insulating layer 140, a first via V1, a second via V2, and a fourth circuit pattern 141.

Further, in an embodiment, the electronic component embedded substrate 100 may further include a first insulating layer 110, a second insulating layer 120, a fifth insulating layer 150, a sixth insulating layer 160, a seventh insulating layer 170, a second circuit pattern 132, a fifth circuit pattern 151, a sixth circuit pattern 161, a third via hole VH3, a fourth via hole VH4, a through via VT, etc.

The electronic component 10 may have an external terminal 11 on one surface thereof to be electrically connected to an external device. At this time, at least two external terminals 11 may be provided. Further, all the surfaces except the surface on which the external terminal 11 is provided may be made of an insulating material.

Here, the electronic component 10 may be an active device formed of various integrated circuits such as MCU or an application processor (AP).

The electronic component 10 may be coupled to the first insulating layer 110. An adhesive member 20 may be provided between the electronic component 10 and the first insulating layer 110 to stably fix the electronic component 10 in the manufacturing process of the electronic component embedded substrate 100.

Further, the adhesive member 20 may be in direct contact with the first insulating layer 110, but a metal pattern 30 and the adhesive member 20 may be in contact with each other in a state in which the metal pattern 30 is formed on the surface of the first insulating layer 110.

This metal pattern 30 may perform a role of assisting heat generated from the electronic component 10 to be smoothly discharged. Further, for this, an opening may be formed in the first insulating layer 110 to expose some areas of the metal pattern 30, and this opening is shown as the fourth via hole VH4 in FIG. 1.

Further, a conductive material may be filled in the fourth via hole VH4 and electrically connected to other devices. In this case, the metal pattern 30 may perform a role of circuit wiring as well as a heat radiation function.

A cavity 133 may be provided in the third insulating layer 130 to insert the electronic component 10 therein.

Further, the third insulating layer 130 may be a core substrate made of a high rigidity material.

At this time, the second circuit pattern 132 may be formed on an upper surface of the third insulating layer 130, and a first circuit pattern 131 may be formed on a lower surface of the third insulating layer 130.

And the first circuit pattern 131 and the second circuit pattern 132 may be electrically connected through the through via VT which passes through the third insulating layer 130.

Like this, when the third insulating layer 130 is a core substrate, it is advantageous to reduction of warpage of the electronic component embedded substrate 100.

The fourth insulating layer 140 may be provided on the third insulating layer 130 and the electronic component 10 and have the fourth circuit pattern 141 on an outer surface thereof. Here, the fourth circuit pattern 141 and the second circuit pattern 132 and the fourth circuit pattern 141 and the external terminal 11 may be electrically connected by the vias passing through the fourth insulating layer 140.

Accordingly, it is possible to secure a signal transmission path for electrically connecting the electronic component 10 to the external device.

For the convenience of understanding, in the present embodiment and drawing, the via for connecting between the fourth circuit pattern 141 and the second circuit pattern 132 will be referred to as the first via V1, and the via for connecting between the fourth circuit pattern 141 and the external terminal 11 will be referred to as the second via V2.

Further, the first via V1 and the second via V2 may have the same height.

Accordingly, it is possible to efficiently perform a via hole forming process, a conductive material plating process, etc. in forming the first via V1 and the second via V2 which pass through the fourth insulating layer 140.

Meanwhile, one surface of the electronic component 10 having the external terminal 11 thereon may be referred to as an active surface, and the other surface of the electronic component 10, which is opposite to the active surface, may be referred to as an inactive surface.

Wiring is provided in the direction of the active surface to connect the external terminal 11 to the external device. At this time, when the electronic component 10 is an active device such as an integrated circuit, the number of the external terminals 11 may be increased. Further, while the density of the external terminal 11 on the active surface is continuously increased according to the trend of high performance and miniaturization of the electronic component 10, the area of the external terminal 11 itself is decreased.

Therefore, the first via V1 for connecting the external terminals 11 to the external device and the fourth circuit pattern 141 connected to the first via V1 are needed to have a high wiring density.

On the other hand, generally, no external terminal 11 is provided on the inactive surface or only significantly fewer external terminals 11 are provided on the inactive surface compared to the active surface. Thus, a high wiring density is not needed.

Considering this, in the electronic component embedded substrate 100 in accordance with an embodiment of the present invention, the fourth insulating layer 140 is made of a material having a low coefficient of thermal expansion to be advantageous to increase a wiring density.

Further, a build-up layer may be further provided on the outer surface of the fourth insulating layer 140 when necessary. Here, the build-up layer means the fifth insulating layer 150, the fifth circuit pattern 151, the sixth insulating layer 160, the sixth circuit pattern 161, etc.

Of course, this build-up layer can be also made of a material having a low coefficient of thermal expansion.

Further, when the density of the external terminal 11 is relatively higher than the wiring density of the second circuit pattern 132, the volume of the second via V2 may be smaller than that of the first via V1.

Meanwhile, when the wiring is formed only in the direction of the active surface of the electronic component 10 like this and the build-up layers are further formed, warpage may be intensified in the manufacturing process of the electronic component embedded substrate 100.

Therefore, in the electronic component embedded substrate 100 according to an embodiment of the present invention, the first insulating layer 110 provided in the direction of the inactive surface of the electronic component 10 may be implemented with a material having a relatively high coefficient of thermal expansion.

Accordingly, it is possible to relieve the warpage even though the wiring and the number of layers are asymmetrically formed with respect to the electronic component 10.

Meanwhile, the second insulating layer 120 may be provided on a bottom surface of the third insulating layer 130.

An upper surface of the second circuit pattern 132 and an upper surface of the external terminal 11 should have the same height in order that the first via V1 and the second via V2 have the same height as described above. That is, the upper surface of the second circuit pattern 132 and the upper surface of the external terminal 11 should be aligned on a line LV1 of FIG. 1.

Here, the third insulating layer 130 and the electronic component 10 are disposed on the first insulating layer 110. Thus, the height of the second circuit pattern 132 and the height of the external terminal 11 are different according to the size relationship of the thickness of the electronic component 10 and the external terminal 11 and the thickness of the third insulating layer 130 and the second circuit pattern 132.

In addition, since the adhesive member 20, the metal pattern 30, etc. may be further provided between the electronic component 10 and the first insulating layer 110, variable factors are increased.

Therefore, the height of the upper surface of the second circuit pattern 132 can be adjusted according to these variable factors. That is, the second insulating layer 120 can perform a function of adjusting the height of the upper surface of the second circuit pattern 132.

For example, when the sum of the thickness of the first circuit pattern 131, the third insulating layer 130, and the second circuit pattern 132 is smaller than the sum of the thickness of the external terminal 11, the electronic component 10, the adhesive member 20, and the metal pattern 30 as shown in FIG. 1, it is possible to adjust the thickness by further forming the second insulating layer 120 that covers the lower surface of the third insulating layer 130.

Meanwhile, in this case, the second insulating layer 120 also covers the first circuit pattern 131. That is, LV2 and LV3 of FIG. 1 may be set differently.

Accordingly, the third via hole VH3, which passes through the first insulating layer 110, also passes through the second insulating layer 120 positioned on a bottom surface of the first circuit pattern 131.

FIG. 2 is a cross-sectional view schematically showing an electronic component embedded substrate 100′ in accordance with another embodiment of the present invention.

Referring to FIG. 2, in the electronic component embedded substrate 100′ according to the present embodiment, a first circuit pattern 131 may be in direct contact with a first insulating layer 110. That is, the present embodiment is different from the above-described embodiment in that LV2 and LV3 of FIG. 2 may be the same.

In this case, a third via hole VH3, which passes through the first insulating layer 110, is not needed to pass through a second insulating layer 120.

Meanwhile, although not shown, a chip component such as a memory chip may be mounted under the first insulating layer 110.

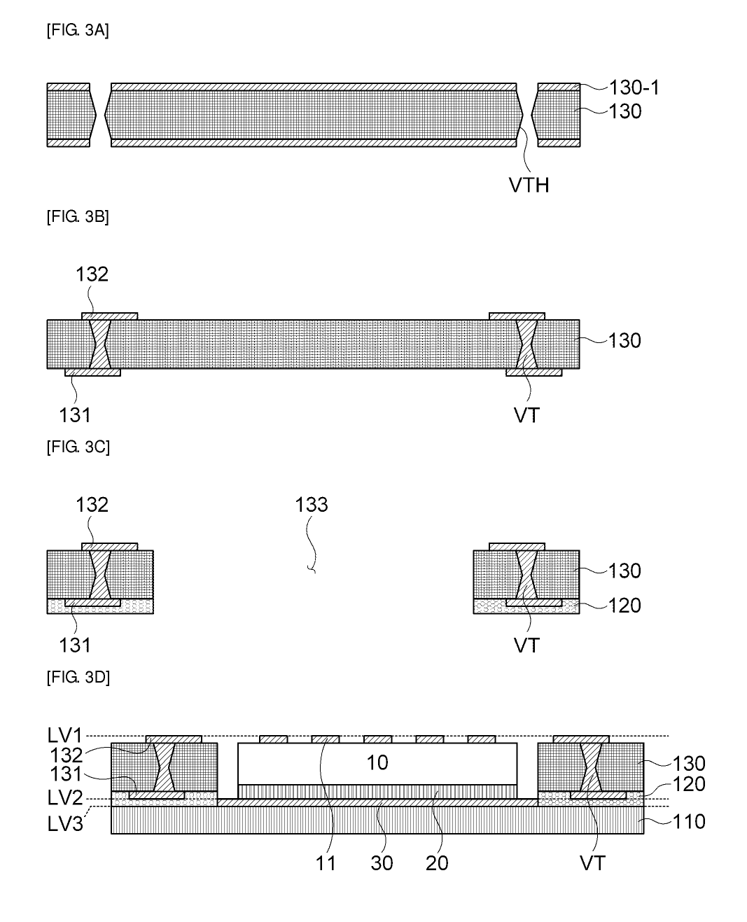

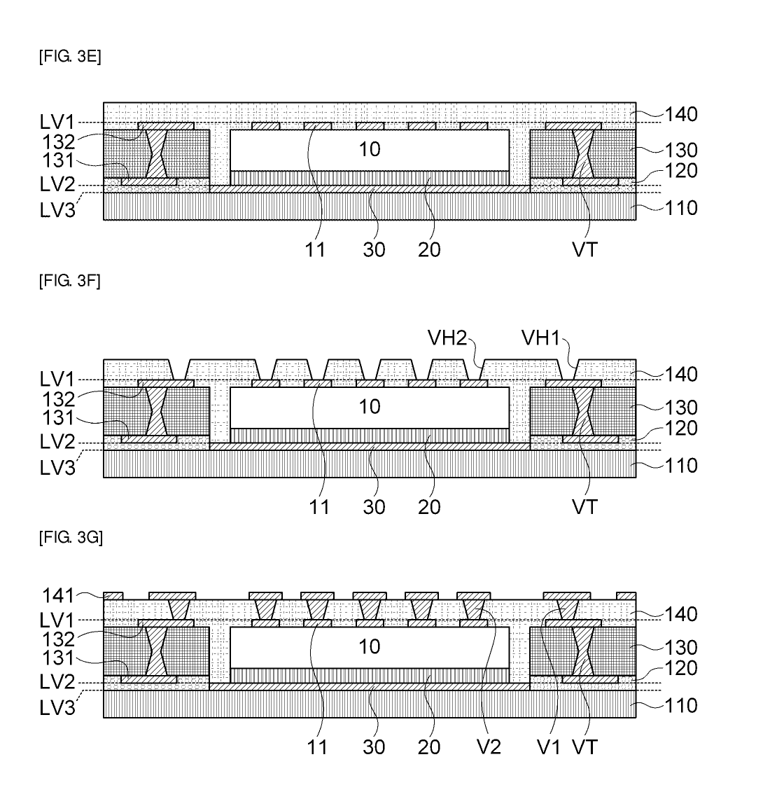

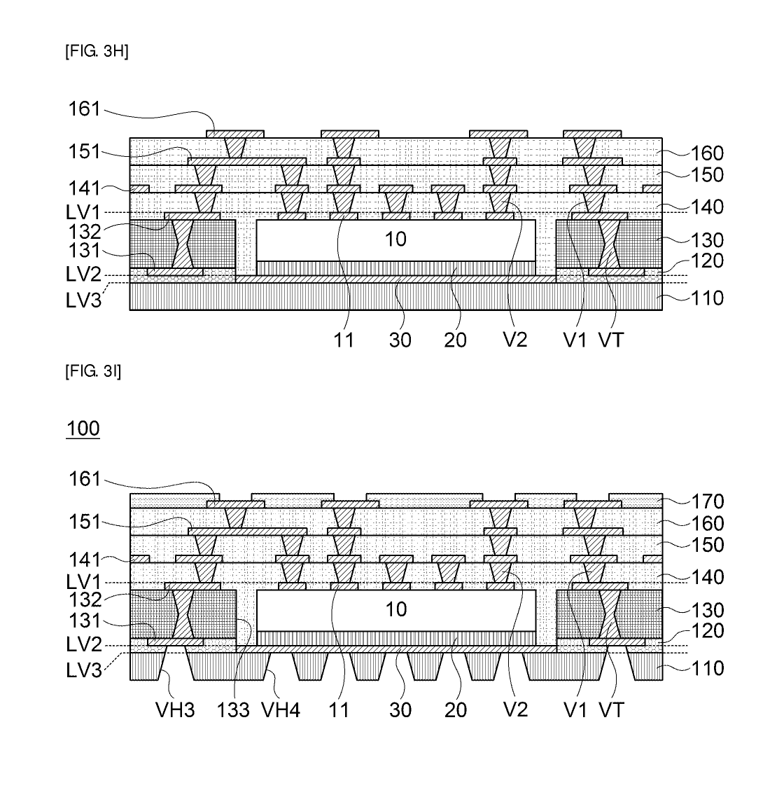

FIGS. 3A to 3I are process cross-sectional views for explaining a method of manufacturing an electronic component embedded substrate 100 in accordance with an embodiment of the present invention.

Hereinafter, the method of manufacturing an electronic component embedded substrate 100 in accordance with an embodiment of the present invention will be described with reference to FIGS. 3A to 3I.

First, FIG. 3A is a process cross-sectional view showing the state in which a through via hole VTH is formed in a third insulating layer 130 in accordance with an embodiment of the present invention, FIG. 3B is a process cross-sectional view showing the state in which a first circuit pattern, a second circuit pattern, and a through via VT are formed in accordance with an embodiment of the present invention, and FIG. 3C is a process cross-sectional view showing the state in which a cavity 133 and a second insulating layer 120 are formed in accordance with an embodiment of the present invention.

Referring to FIGS. 3A to 3C, it will be understood that the through via hole VTH is formed in the third insulating layer 130 and the first circuit pattern 131, the second circuit pattern 132, and the through via VT for connecting them are formed.

Further, the cavity 133 is formed in the third insulating layer 130 to accommodate an electronic component 10 therein.

At this time, the second insulating layer 120 may be formed in a state in which the first circuit pattern 131 is formed, and the cavity 133 may be formed to pass through both of the third insulating layer 130 and the second insulating layer 120.

Meanwhile, the third insulating layer 130 may be a core substrate made of a high rigidity material. At this time, in the core substrate, a metal material 130-1 such as copper foil may be provided on the surface of an insulating material. As an embodiment, a copper clad laminate (CCL) may be used as the core substrate.

FIG. 3D is a process cross-sectional view showing the state in which the third insulating layer 130 and the electronic component 10 are coupled on a first insulating layer 110 in accordance with an embodiment of the present invention.

Referring to FIG. 3D, a surface of the electronic component 10, which is opposite to the surface having an external terminal 11 formed thereon, that is, the above-described inactive surface may be disposed to face the first insulating layer 110. Here, an adhesive member 20 and a metal pattern 30 may be further provided between the electronic component 10 and the first insulating layer 110.

Meanwhile, the third insulating layer 130 may be disposed so that a lower surface of the first circuit pattern 131 faces the first insulating layer 110.

At this time, when an upper surface of the second circuit pattern 132 doesn't reach LV1 due to the insufficient thickness of the third insulating layer 130, the first circuit pattern 131, and the second circuit pattern 132, the third insulating layer 130 may be disposed on the first insulating layer 110 in a state in which the second insulating layer 120 covering the first circuit pattern 131 is provided.

Further, although not shown, when the upper surface of the second circuit pattern 132 reaches LV1 only by the thickness of the third insulating layer 130, the first circuit pattern 131, and the second circuit pattern 132, the second insulating layer 120 may not cover the first circuit pattern 131.

Like this, the next process is performed in a state in which the upper surface of the second circuit pattern 132 and an upper surface of the external terminal 11 are aligned with LV1.

FIG. 3E is a process cross-sectional view showing the state in which a fourth insulating layer 140 is formed in accordance with an embodiment of the present invention, FIG. 3F is a process cross-sectional view showing the state in which a first via hole VH1 and a second via hole VH2 are formed in accordance with an embodiment of the present invention, and FIG. 3G is a process cross-sectional view showing the state in which a first via V1, a second via V2, and a fourth circuit pattern 141 are formed in accordance with an embodiment of the present invention.

Referring to FIGS. 3E to 3G, the fourth insulating layer 140, which covers the third insulating layer 130 and the electronic component 10, may be provided.

At this time, when the density of the external terminal 11 is high, the density of wiring consisting of the fourth circuit pattern 141, the first via V1, and the third via V3, which are to be formed on the fourth insulating layer 140, should be high.

It is preferred that the fourth insulating layer 140 is made of a material having a low coefficient of thermal expansion to efficiently implement a high wiring density like this.

Further, after the fourth insulating layer 140 is formed, the first via hole VH1 and the second via hole VH2 are formed, and the first via hole VH1 and the second via hole VH2 are filled with a conductive material and the fourth circuit pattern 141 is formed at the same time.

FIG. 3H is a process cross-sectional view showing the state in which a build-up layer is further formed in accordance with an embodiment of the present invention, and FIG. 3I is a process cross-sectional view showing the state in which a third via hole VH3, a fourth via hole VH4, and a seventh insulating layer 170 are formed in accordance with an embodiment of the present invention.

Referring to FIGS. 3H and 3I, when the fourth insulating layer 140 is not enough due to too high wiring density, the build-up layer including a fifth insulating layer 150, a fifth circuit pattern 151, a sixth insulating layer 160, and a sixth circuit pattern 161 may be further formed.

At this time, it is preferred that the fifth insulating layer 150 and the sixth insulating layer 160 are also made of a material having a relatively low coefficient of thermal expansion.

Meanwhile, the sixth circuit pattern 161 may be a contact pad in contact with a solder ball for connecting the electronic component embedded substrate 100 to another substrate or device.

And the seventh insulating layer 170 may be a solder resist that covers the rest of the sixth insulating layer 160 and the sixth circuit pattern 161 while exposing a portion of the sixth circuit pattern 161.

Further, the third via hole VH3 and the fourth via hole VH4 may be further formed to pass through the first insulating layer 110.

At this time, the fourth via hole VH4 may expose the metal pattern 30 to the outside to improve heat radiation performance. Further, the fourth via hole VH4 may be filled with a conductive material to electrically connect another external device to the metal pattern 30.

Meanwhile, the third via hole VH3 may be formed to expose the first circuit pattern 131.

Accordingly, when a chip component (not shown) is electrically connected through the third via hole VH3, a signal transmission path can be implemented between the electronic component 10 and the chip component through the first circuit pattern 131, the through via VT, the second circuit pattern 132, the first via, the fourth circuit pattern 141, and the second via V2.

Further, a signal transmission path or a power transmission path can be implemented between the external device and the chip component connected to the electronic component embedded substrate 100 through the first circuit pattern 131, the through via VT, the second circuit pattern 132, the first via V1, the fourth circuit pattern 141, the via formed in the fifth insulating layer 150, the fifth circuit pattern 151, the via formed in the sixth insulating layer 160, and the sixth circuit pattern 161.

The present invention configured as above can improve efficiency of a process of forming a via for connecting an electronic component embedded in a substrate to external wiring and relieve warpage while minimizing formation of unnecessary wiring on the electronic component embedded substrate.

What is claimed is:

1. An electronic component embedded substrate comprising:
an electronic component having at least one external terminal on at least one surface thereof;
a third insulating layer having a second circuit pattern on one surface thereof and a cavity to insert the electronic component therein;
a fourth insulating layer provided on the third insulating layer and the electronic component;
a first via having one surface in contact with the second circuit pattern through the fourth insulating layer;
a second via having one surface in contact with the external terminal through the fourth insulating layer; and
a fourth circuit pattern provided on an outer surface of the fourth insulating layer to be in contact with the other surface of the first via and the other surface of the second via, wherein the first via and the second via have the same distance from one surface to the other surface.

2. The electronic component embedded substrate according to claim 1, further comprising:
a first insulating layer provided on the other surface of the electronic component and the other surface of the third insulating layer; and
a second insulating layer provided between the other surface of the third insulating layer and the first insulating layer.

3. The electronic component embedded substrate according to claim 2, wherein the third insulating layer further comprises:
a through via passing through the third insulating layer; and
a first circuit pattern electrically connected to the second circuit pattern by the through via.

4. The electronic component embedded substrate according to claim 3, wherein the second insulating layer is formed to cover the second circuit pattern, and further comprising:
a third via hole which exposes the second circuit pattern through the first insulating layer and the second insulating layer.

5. The electronic component embedded substrate according to claim 4, wherein an insulating material forming the fourth insulating layer has a lower coefficient of thermal expansion than an insulating material forming the first insulating layer.

6. The electronic component embedded substrate according to claim 5, further comprising:
at least one build-up layer provided on the fourth insulating layer, wherein an insulating material forming the build-up layer has a lower coefficient of thermal expansion than the insulating material forming the first insulating layer.

7. The electronic component embedded substrate according to claim 3, wherein the first circuit pattern is in contact with the first insulating layer, and further comprising:
a third via hole which exposes the first circuit pattern through the first insulating layer.

8. The electronic component embedded substrate according to claim 2, further comprising:
an adhesive member having one surface in contact with the other surface of the electronic component.

9. The electronic component embedded substrate according to claim 8, further comprising:
a metal pattern having one surface in contact with the other surface of the adhesive member.

10. The electronic component embedded substrate according to claim 9, further comprising:
a fourth via hole which exposes the metal pattern to the outside through the first insulating layer.

11. The electronic component embedded substrate according to claim 1, wherein the first via has a larger volume than the second via.

12. A method of manufacturing an electronic component embedded substrate, comprising:
providing a third insulating layer which is penetrated by a cavity, has a second circuit pattern on one surface thereof, has a first circuit pattern on the other surface thereof, and electrically connects the second circuit pattern and the first circuit pattern by a through via;
disposing an electronic component, which has at least one external terminal on at least one surface thereof, and the third insulating layer on a first insulating layer;
forming a fourth insulating layer on the third insulating layer and the electronic component;
forming a first via hole, which exposes the second circuit pattern through the fourth insulating layer, and a second via hole, which exposes the external terminal through the fourth insulating layer; and
forming a first via by filling a conductive material in the first via hole, forming a second via by filling a conductive material in the second via hole, and forming a fourth circuit pattern on the fourth insulating layer, wherein the first via and the second via has the same distance from one surface to the other surface.

13. The method of manufacturing an electronic component embedded substrate according to claim 12, wherein in providing the third insulating layer, a second insulating layer is further formed to cover the other surface of the third insulating layer.

14. The method of manufacturing an electronic component embedded substrate according to claim 13, wherein an insulating material forming the fourth insulating layer has a lower coefficient of thermal expansion than an insulating material forming the first insulating layer.

15. The method of manufacturing an electronic component embedded substrate according to claim 14, further comprising:
forming at least one build-up layer on the fourth insulating layer, wherein an insulating material forming the build-up layer has a lower coefficient of thermal expansion than the insulating material forming the first insulating layer.

16. The method of manufacturing an electronic component embedded substrate according to claim 15, further comprising:
forming a via hole passing through the first insulating layer.

17. The method of manufacturing an electronic component embedded substrate according to claim 12, wherein the first via has a larger volume than the second via.
